(19) United States
(12) Patent Application Publication
(10) Pub. No.: US 2026/0114088 A1
(43) Pub. Date: Apr. 23, 2026

(54) MICRO-CHIP AND DISPLAY DEVICE INCLUDING THE SAME

(71) Applicants: Samsung Electronics Co., Ltd., Suwon-si (KR); Tech University of Korea Industry Academic Cooperation Foundation, Siheung-si (KR)

(72) Inventors: Kyungwook HWANG, Suwon-si (KR); Kyungtaek MIN, Siheung-si (KR); Dongho KIM, Suwon-si (KR); Taehun KIM, Siheung-si (KR); Jiwon LEE, Siheung-si (KR); Junsik HWANG, Suwon-si (KR)

(73) Assignees: Samsung Electronics Co., Ltd., Suwon-si (KR); Tech University of Korea Industry Academic Cooperation Foundation, Siheung-si (KR)

(21) Appl. No.: 18/917,622

(22) Filed: Oct. 16, 2024

(30) Foreign Application Priority Data
Dec. 26, 2023 (KR) 10-2023-0191855

(51) Int. Cl. H10H 20/84; H10H 20/80; H10H 20/816; H10H 20/819; H10H 29/49

(52) U.S. Cl. CPC H10H 20/84; H10H 20/816; H10H 20/819; H10H 20/882; H10H 29/49

(57) ABSTRACT

A microchip includes a first semiconductor layer having a first conductivity type and extending along one plane, a light emitting layer on an upper surface of the first semiconductor layer, a second semiconductor layer on an upper surface of the light emitting layer and having a second conductivity type that is electrically opposite to the first conductivity type, an insulating layer on an upper surface of the second semiconductor layer, and a current spreading layer between the second semiconductor layer and the insulating layer, where the insulating layer includes a material having a refractive index that is less than or equal to 1.5, and the current spreading layer has a thickness that is in a range of about 5 nm to about 50 nm.

### CROSS-REFERENCE TO RELATED APPLICATION

This application is based on and claims priority under 35 U.S.C. § 119 to Korean Patent Application No. 10-2023-0191855, filed on Dec. 26, 2023, in the Korean Intellectual Property Office, the disclosure of which is incorporated by reference herein in its entirety.

### BACKGROUND

### 1. Field

The disclosure relates to a microchip and a display device including the same.

### 2. Description of Related Art

The industrial demand for light emitting diodes (LEDs) has increased due to their advantages of low power consumption and environmental friendliness. LEDs are used not only in lighting devices and liquid crystal display (LCD) backlights, but also as pixels in display devices. Recently, micro-LED display devices that include micro-unit LED chips as pixels have been developed.

In manufacturing microchips, as the size of a microchip decreases and the size of a display device increases, there may be limitations in improving the light efficiency by improving the structural defects of a microchip.

### SUMMARY

Provided are a microchip which may have improved light extraction efficiency and a display device including the same.

Provided are also a microchip which may have a structure suitable for alignment using a fluid self-assembly and a display device including the same.

Additional aspects will be set forth in part in the description which follows and, in part, will be apparent from the description, or may be learned by practice of the presented embodiments of the disclosure.

According to an aspect of the disclosure, a microchip may include a first semiconductor layer having a first conductivity type and extending along one plane, a light emitting layer on an upper surface of the first semiconductor layer, a second semiconductor layer on an upper surface of the light emitting layer and having a second conductivity type that is electrically opposite to the first conductivity type, an insulating layer on an upper surface of the second semiconductor layer, and a current spreading layer between the second semiconductor layer and the insulating layer, where the insulating layer may include a material having a refractive index that is less than or equal to 1.5, and the current spreading layer may have a thickness that is in a range of about 5 nm to about 50 nm.

The insulating layer may have a thickness that is in a range of about 220 nm to about 270 nm.

The insulating layer may have a thickness that is in a range of about 350 nm to about 420 nm.

The insulating layer may have a thickness that is in a range of about 520 nm to about 580 nm.

The insulating layer may have a thickness that is in a range of about 680 nm to about 720 nm.

The light emitting layer may be configured to emit light in a wavelength that is in a range of about 380 nm to and about 500 nm.

The insulating layer may include at least one of SiO₂ and MgF₂.

The current spreading layer may include at least one of indium tin oxide (ITO), ZnO, and indium gallium zinc oxide (IGZO).

The microchip may include a first electrode on an upper surface of the insulating layer and connected to the first semiconductor layer, and a second electrode on the upper surface of the insulating layer and connected to the second semiconductor layer.

The microchip may include a first surface having a width that is greater than of the upper surface of the insulating layer.

The microchip may include a first surface having a width that is in a range of about 5 μm to about 100 μm.

The microchip may include a first surface, and a distance between the first surface and the upper surface of the insulating layer is in a range of about 1 μm to about 10 μm.

The microchip may include a planarization layer on a lower surface of the first semiconductor layer.

The planarization layer may include at least one of aluminum nitride, polyimide, and parylene.

The microchip may include a plurality of light scattering patterns in the first semiconductor layer, where each of the plurality of light scattering patterns has a triangle-shape on the lower surface of the first semiconductor layer that contacts an upper surface of the planarization layer.

The microchip may include a plurality of light scattering patterns in the planarization layer, where the plurality of light scattering patterns have an cone shape or triangle shape with a base on an upper surface of the planarization layer.

The microchip may include a plurality of light scattering patterns penetrating the planarization layer and having a cone shape or triangle shape with a base on the lower surface of the first semiconductor layer.

According to an aspect of the disclosure, a display device may include a circuit board including a driving circuit, and a plurality of microchips on the circuit board, where each of the plurality of microchips may include a first semiconductor layer having a first conductivity type and extending along one plane, a light emitting layer on an upper surface of the first semiconductor layer, a second semiconductor layer on an upper surface of the light emitting layer and having a second conductivity type that is electrically opposite to the first conductivity type, an insulating layer on an upper portion of the second semiconductor layer, and a current spreading layer between the second semiconductor layer and the insulating layer, where the insulating layer may include a material having a refractive index of 1.5 or less, and the current spreading layer may have a thickness that is in a range of about 5 nm to about 50 nm.

The insulating layer may have a thickness that is in a range of about 220 nm to about 270 nm.

The insulating layer may have a thickness that is in a range of about 350 nm to about 420 nm.

The insulating layer may have a thickness that is in a range of about 520 nm to about 580 nm.

The insulating layer may have a thickness that is in a range of about 680 nm to about 720 nm.

The light emitting layer may be configured to emit light in a wavelength that is in a range of about 380 nm to about 500 nm.

The display device may include a plurality of first electrode pads on a first surface of the circuit board and a plurality of second electrode pads on the first surface of the circuit board, and each of the plurality of microchips may include a first electrode on an upper surface of the insulating layer and connected to the first semiconductor layer and a second electrode on the upper surface of the insulating layer and connected to the second semiconductor layer, where the first electrode of each of the plurality of microchips contacts one of the plurality of first electrode pads, and the second electrode of each of the plurality of microchips contacts one of the plurality of second electrode pads.

According to an aspect of the disclosure, a microchip may include a first semiconductor layer having a first conductivity type, a light emitting layer on an upper surface of the first semiconductor layer, a second semiconductor layer on an upper surface of the light emitting layer and having a second conductivity type that is electrically opposite to the first conductivity type, an insulating layer on an upper surface of the second semiconductor layer, a current spreading layer between the second semiconductor layer and the insulating layer, a via hole extending through the current spreading layer, the insulating layer, the second semiconductor layer, and the light emitting layer, and extending partially through the first semiconductor layer, and a first electrode in the via hole, the first electrode including a first portion contacting the first semiconductor layer, where light emitted by the light emitting layer toward an upper surface of the microchip is reflected by the first electrode toward a lower surface of the microchip.

The microchip may include a second electrode adjacent to the first electrode and on the upper surface of the microchip, where the second electrode may include a portion that extends through the insulating layer and the current spreading layer, and that contacts the second semiconductor layer.

The lower surface of the microchip may have a width that is greater than a width of the upper surface of the microchip.

A portion of the insulating layer may extend in the via hole.

The first electrode further may include a second portion extending over an upper surface of the insulating layer, and the light emitted by the light emitting layer toward the upper surface of the microchip may be reflected by a lower surface of the second portion of the first electrode.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a perspective view illustrating a display device according to one or more embodiments;

FIG. 2 is a cross-sectional view illustrating a structure of a display device according to one or more embodiments;

FIG. 3 is a plan view illustrating a microchip according to one or more embodiments;

FIG. 4 is a cross-sectional view illustrating a structure of the microchip according to one or more embodiments;

FIG. 5 is a cross-sectional view illustrating a microchip according to one or more embodiments;

FIG. 6 is an enlarged cross-sectional view illustrating a region M shown in FIG. 5 according to one or more embodiments;

FIG. 7 is a graph illustrating reflectance according to a thickness change of an insulating layer, according to one or more embodiments;

FIG. 8 is a graph illustrating light extraction efficiency according to a length of a width of the microchip, according to one or more embodiments;

FIG. 9 is a perspective view illustrating a method of aligning a plurality of microchips using a fluid self-assembly method according to one or more embodiments;

FIG. 10 is a cross-sectional view illustrating a structure of a microchip according to one or more embodiments;

FIG. 11 is a cross-sectional view illustrating a structure of a microchip according to one or more embodiments;

FIG. 12 is a cross-sectional view illustrating a structure of a microchip according to one or more embodiments;

FIG. 13 is a cross-sectional view illustrating a structure of a microchip according to one or more embodiments;

FIG. 14 is a graph illustrating light extraction efficiency according to a length of a width of the microchip, according to one or more embodiments;

FIG. 15 is a block diagram illustrating an electronic device according to one or more embodiments;

FIG. 16 is a diagram illustrating an example in which a display device is applied to a mobile device according to one or more embodiments;

FIG. 17 is a diagram illustrating an example in which a display device is applied to a display device for vehicles according to one or more embodiments;

FIG. 18 is a diagram illustrating an example in which a display device is applied to augmented reality glasses or virtual reality glasses according to one or more embodiments;

FIG. 19 is a diagram illustrating an example in which a display device is applied to signage according to one or more embodiments; and

FIG. 20 is a diagram illustrating an example in which a display device is applied to a wearable display according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments, including a microchip and a display device including the same, are described in detail with reference to the attached drawings. Like reference numerals in the drawings denote like elements, and the size of each element in the drawings may be exaggerated for clarity and convenience of description. Embodiments described below are merely examples, and various modifications may be made from these embodiments.

In the following description, when a component is referred to as being “above” or “on” another component, it may be directly on an upper, lower, left, or right side of the other component while making contact with the other component or may be above an upper, lower, left, or right side of the other component without making contact with the other component. The terms of a singular form may include plural forms unless otherwise specified. In addition, when a certain part “includes” a certain component, it means that other components may be further included rather than excluding other components unless otherwise stated.

Terms such as first, second, etc. may be used to describe various components, but are used only for the purpose of distinguishing one component from another component. These terms do not limit the difference in the material or structure of the components.

The term “the” and the similar indicative terms may be used in both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

In addition, terms such as “unit” and “module” described in the specification may indicate a unit that processes at least one function or operation, and this may be implemented as hardware or software, or may be implemented as a combination of hardware and software.

Connections of lines or connection members between elements shown in the drawings are illustrative of functional connections and/or physical or circuitry connections, and may be replaced in an actual device, or may be represented as additional various functional connections, physical connections, or circuitry connections.

The use of all examples or example terms is merely for describing the technical concept in detail, and the scope thereof is not limited by these examples or example terms unless limited by claims.

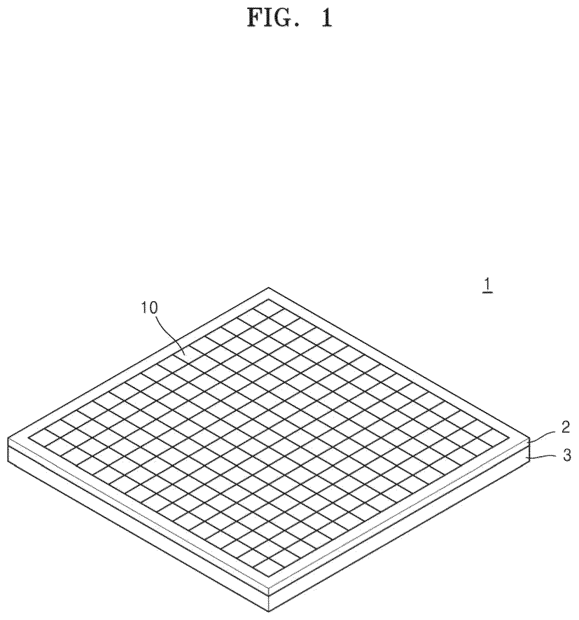

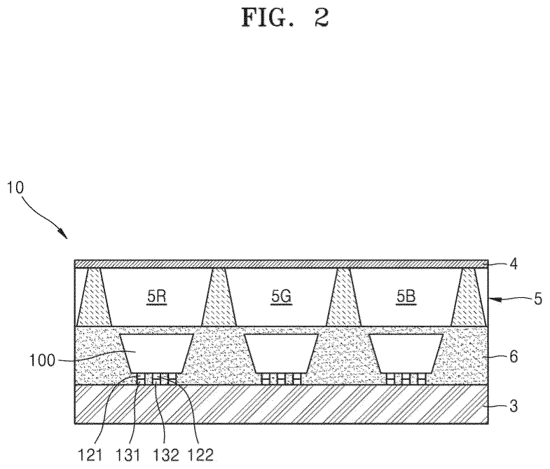

FIG. 1 is a perspective view illustrating a display device 1 according to one or more embodiments. FIG. 2 is a cross-sectional view illustrating a structure of a display device 1 according to one or more embodiments.

Referring to FIGS. 1 and 2, the display device 1 according to one or more embodiments may include a circuit board 3 and a display panel 2 arranged on the circuit board 3.

The display panel 2 may include a plurality of semiconductor light emitting devices 10 capable of emitting light mixed with red (R), green (G), and blue (B) light. Each of the plurality of semiconductor light emitting devices 10 may constitute one pixel on the display panel 2 and the plurality of semiconductor light emitting devices 10 may be arranged in rows and columns on the circuit board 3. FIG. 1 shows that the plurality of semiconductor light emitting devices 10 are arranged in 15 rows and 15 columns, but this is only for convenience of explanation, and in implementation, a larger number of semiconductor light emitting devices 10 may be arranged depending on the required resolution.

Each of the plurality of semiconductor light emitting devices 10 may include a plurality of sub-pixels corresponding to RGB light sources, and the plurality of sub-pixels in one semiconductor light emitting device 10 may be provided in a structure disposed adjacent to each other. This will be described in detail with reference to FIG. 2. However, FIG. 2 shows one pixel including three sub-pixels corresponding to the RGB light sources, but is not limited thereto, and four or more sub-pixels may be included in one pixel. For example, various colors such as cyan, yellow, magenta, and black (CYMK) may be used as sub-pixels.

A driver configured to supply power to the semiconductor light emitting device 10 of the display panel 2 and a control circuit to control the driver may be disposed on the circuit board 3. The circuit board 3 may include a circuit configured to independently drive each pixel (and sub-pixels thereof). For example, the circuit board 3 may include a thin film transistor (TFT).

The semiconductor light emitting device 10 may include a plurality of microchips 100 disposed on the circuit board 3, an insulating layer 6 covering the plurality of microchips 100, and disposed on the insulating layer 6 to fill spaces between the plurality of microchips 100, and a wavelength conversion layer 5 disposed on the insulating layer 6. In addition, the display device 1 may further include an upper substrate 4 disposed on the wavelength conversion layer 5.

The wavelength conversion layer 5 may include a first wavelength conversion layer 5R that converts light emitted from the microchip 100 into light in a first wavelength band, a second wavelength conversion layer 5G that converts the light in a second wavelength band different from the first wavelength band, and a third wavelength conversion layer 5B that converts the light in a third wavelength band different from the first wavelength band and the second wavelength band. For example, the light in the first wavelength band may be red light, the light in the second wavelength band may be green light, and the light in the third wavelength band may be blue light. The first wavelength conversion layer 5R, the second wavelength conversion layer 5G, and the third wavelength conversion layer 5B are arranged to be spaced apart from each other with a diaphragm therebetween, and each may be arranged to face the corresponding microchip 100.

When the microchip 100 emits blue light, the third wavelength conversion layer 5B may include a resin that transmits the blue light. The second wavelength conversion layer 5G may convert the blue light emitted from the microchip 100 to emit the green light. The second wavelength conversion layer 5G may include quantum dots or phosphors that are excited by the blue light and emit the green light. The first wavelength conversion layer 5R may convert the blue light emitted from the microchip 100 to emit the red light. The first wavelength conversion layer 5R may include quantum dots or phosphors that are excited by the blue light and emit the red light.

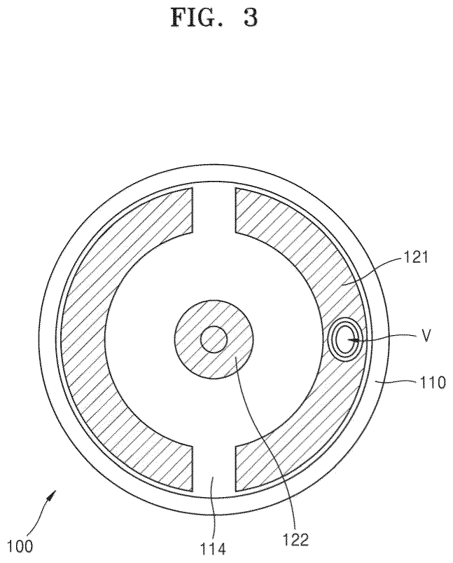

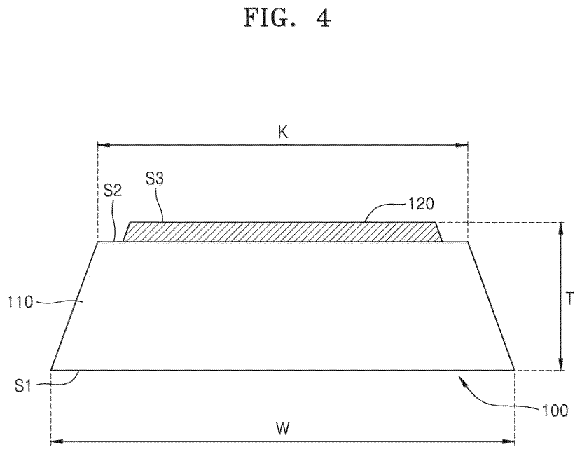

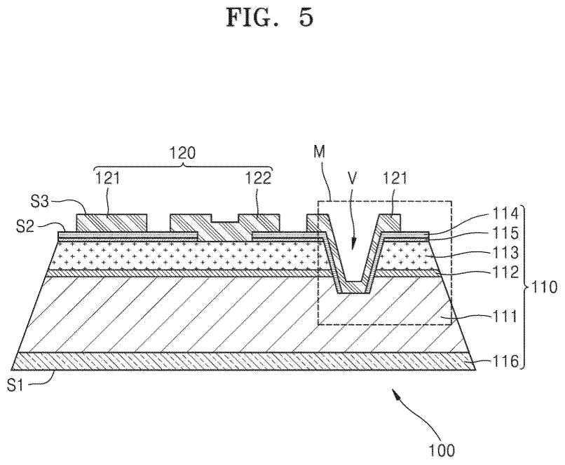

FIG. 3 is a plan view illustrating a microchip 100 according to one or more embodiments. FIG. 4 is a cross-sectional view illustrating a structure of the microchip 100 according to one or more embodiments. FIG. 5 is a cross-sectional view illustrating a microchip 100 according to one or more embodiments.

Referring to FIGS. 3 to 5, the microchip 100 according to one or more embodiments may include a chip body 110 having a first surface S1 and a second surface S2 opposite the first surface S1. An electrode portion 120 may be disposed on the second surface S2 of the chip body 110.

As described above, the microchip 100 may be included in an ultra-small light emitting device such as a micro light emitting diode (LED), but is not necessarily limited thereto. The microchip 100 according to one or more embodiments may include any semiconductor chip, an electronic circuit chip, or an optical circuit chip that may be aligned on a substrate. For example, the microchip 100 may include, in addition to the micro LED, a small light emitting device such as a laser diode, a light receiving device such as a small photodetector such as a photodiode, a small electronic device such as a complementary metal-oxide-semiconductor (CMOS) or high electron mobility transistor (HEMT), a thin film battery, an ultra-small antenna device, etc. Hereinafter, the case where the microchip 100 is a micro LED will be described.

The chip body 110 may include a first semiconductor layer 111 doped with a first conductivity type dopant (i.e., having a first conductivity type) and extending along one plane, a light emitting layer 112 disposed on an upper surface of the first semiconductor layer 111, a second semiconductor layer 113 disposed on an upper surface of the light emitting layer 112 and doped with a second conductivity type dopant (i.e., having a second conductivity type), the second conductivity type being electrically opposite to the first conductivity type, an insulating layer 114 disposed on an upper surface of the second semiconductor layer 113, a current spreading layer 115 disposed between the second semiconductor layer 113 and the insulating layer 114, and a planarization layer 116 disposed on a lower surface of the first semiconductor layer 111.

In addition, the electrode portion 120 may include a first electrode 121 disposed on an upper surface of the insulating layer 114 and electrically connected to the first semiconductor layer 111, and a second electrode 122 disposed on the upper surface of the insulating layer 114 and electrically connected to the second semiconductor layer 113. In this case, the first surface S1 of the chip body 110 may correspond to a lower surface of the planarization layer 116, the second surface S2 of the chip body 110 may correspond to the upper surface of the insulating layer 114, and the upper surface S3 of the electrode portion 120 may correspond to upper surfaces of the first electrode 121 and the second electrode 122.

The first semiconductor layer 111 and the second semiconductor layer 113 may include, for example, a group III-V compound semiconductor or a group II-VI compound semiconductor. The first semiconductor layer 111 and the second semiconductor layer 113 may serve to provide electrons and holes to the light emitting layer 112. To this end, the first semiconductor layer 111 and the second semiconductor layer 113 may be doped with electrically opposite type dopants. For example, the first semiconductor layer 111 may be doped with the n-type dopant and the second semiconductor layer 113 may be doped with the p-type dopant, or the first semiconductor layer 111 may be doped with the p-type dopant and the second semiconductor layer 113 may be doped with the n-type dopant.

The light emitting layer 112 may have a quantum well structure in which a quantum well is disposed between barriers. Light may be generated as electrons and holes provided from the first semiconductor layer 111 and the second semiconductor layer 113 are recombined within the quantum well in the light emitting layer 112. A wavelength of light generated from the light emitting layer 112 may be determined according to an energy band gap of a material constituting the quantum well in the light emitting layer 112. Light emitted from the light emitting layer 112 according to one or more embodiments may have a wavelength of 380 nm or more and 500 nm or less. However, the disclosure is not limited thereto, and the light emitting layer 112 may emit light of different wavelengths.

The light emitting layer 112 may have only one quantum well, but may have a multi-quantum well (MQW) structure in which a plurality of quantum wells and a plurality of barriers are alternately arranged. A thickness of the light emitting layer 112 or the number of quantum wells in the light emitting layer 112 may be appropriately selected in consideration of a driving voltage and light emitting efficiency of the light emitting device.

According to one or more embodiments, both the first electrode 121 and the second electrode 122 may be disposed on one surface of the microchip 100. For example, the insulating layer 114 may be formed on the upper surface of the second semiconductor layer 113, and the first electrode 121 and the second electrode 122 may be disposed on the upper surface of the insulating layer 114. In order to electrically connect the first electrode 121 to the first semiconductor layer 111, the microchip 100 may further include a via hole V penetrating the second semiconductor layer 113 and the light emitting layer 112. FIG. 5 shows only one via hole V for convenience, but one or more via holes V may be formed as needed. The insulating layer 114 may extend to surround a sidewall of the via hole V. Accordingly, a part of the second semiconductor layer 113 and a part of the light emitting layer 112 exposed by the via hole V may be covered by the insulating layer 114. The first electrode 121 may extend from the upper surface of the insulating layer 114 to the upper surface of the first semiconductor layer 111 exposed through the via hole V and contact the first semiconductor layer 111 through the via hole V. The second electrode 122 may be configured to penetrate the insulating layer 114 and contact the second semiconductor layer 113. Parts of the first electrode 121 and the second electrode 122 may further extend from the upper surface of the insulating layer 114 in a lateral direction.

In the above-described embodiment, both the first electrode 121 and the second electrode 122 may be disposed on one surface of the microchip 100, but the disclosure is not limited thereto. For example, the first electrode 121 and the second electrode 122 may be disposed on different surfaces of the microchip 100. For example, the first electrode 121 may be disposed to contact the lower surface of the first semiconductor layer 111 to electrically connect to the first semiconductor layer 111. At this time, the second electrode 122 may be configured to penetrate the insulating layer 114 and contact the second semiconductor layer 113.

The planarization layer 116 serves to provide the first surface S1 for easily aligning the microchips 100 on the circuit board 3. To this end, the planarization layer 116 may have a very smooth and flat lower surface. In addition, the planarization layer 116 according to one or more embodiments may include a material having hydrophilicity. For example, the planarization layer 116 may include at least one material of aluminum nitride (AlN), polyimide, or parylene. Accordingly, the first surface S1 of the chip body 110 may have hydrophilicity.

Meanwhile, after aligning the microchips 100, electrical wiring may be connected to each of the first electrode 121 and the second electrode 122. For example, as shown in FIG. 2, in a process of manufacturing the display device 1, the first electrode 121 and the second electrode 122 of the microchip 100 may be respectively bonded to corresponding electrode pads 131 and 132 on the circuit board 3. For example, a plurality of first electrode pads 131 and a plurality of second electrode pads 132 may be disposed on the surface of the circuit board 3. At this time, the first electrode 121 of each of the plurality of microchips 100 may be connected to contact one of the plurality of first electrode pads 131. In addition, the second electrode 122 of each of the plurality of microchips 100 may be connected to contact one of the plurality of second electrode pads 132. In order to easily implement such an electrical connection, the first electrode 121 and the second electrode 122 may have a symmetrical shape.

For example, a cross-section of the microchip 100 may have a circular shape. The second electrode 122 may be disposed at the center of the microchip 100, that is, at a position corresponding to the center of the second semiconductor layer 113 in a vertical direction. The second electrode 122 may have a circular shape. However, the second electrode 122 is not necessarily limited thereto, and may have a square or other polygonal shape. The first electrode 121 may be disposed at an edge of the microchip 100, that is, at a position corresponding to the edge of the second semiconductor layer 113 in the vertical direction. The first electrode 121 may have a symmetrical shape with respect to the second electrode 122. For example, the first electrode 121 may have a shape of two broken semicircular rings surrounding the second electrode 122. FIG. 3 shows the first electrode 121 having the shape of two broken rings, but the first electrode 121 is not necessarily limited thereto. The first electrode 121 may have the shape of, for example, three or four or more rings that are broken apart from each other. Even though the first electrode 121 has parts broken apart from each other, the parts may be electrically connected to each other when the first electrode 121 is bonded to the first electrode pad 131 on the circuit board 3. In addition, FIG. 3 shows only one via hole V for convenience, but one or more via holes V may be formed as needed.

When the planarization layer 116 includes aluminum nitride (AlN), the planarization layer 116 may also serve as a buffer layer for growing the first semiconductor layer 111, the light emitting layer 112, and the second semiconductor layer 113, for example, on a growth substrate such as a silicon substrate. After manufacturing the microchip 100 on the growth substrate, the microchip 100 may be separated from the growth substrate through a chemical lift off. When the microchip 100 is separated through the chemical lift off, a lower surface of the planarization layer 116 including aluminum nitride (AlN) may be very smooth. When the planarization layer 116 includes polyimide or parylene, after manufacturing the microchip 100 on the growth substrate, the planarization layer 116 may be formed on a lower surface of the first semiconductor layer 111, for example, by flip chip bonding. Then, the lower surface of the planarization layer 116 may be planarized using, for example, chemical mechanical polishing (CMP).

According to one or more embodiments, when aligning the plurality of microchips 100 on an external object such as a substrate, most or all of the plurality of microchips 100 may be aligned in the same direction. For example, the plurality of microchips 100 may be aligned so that the first surface S1 of the chip body 110 contacts the external object and the upper surface S3 of the electrode portion 120 does not contact the external object. Here, the upper surface S3 of the electrode portion 120 is a surface opposite to the surface of the electrode portion 120 that contacts the second surface S2 of the chip body 110.

Referring back to FIG. 4, the microchip 100 may have a small size of submillimeter (mm) or less. For example, a width W of the first surface S1 of the chip body 110 may be in the range of about 5 μm or more and about 100 μm or less, or in the range of about 10 μm to about 50 μm. For example, when the microchip 100 has a circular cross-section as shown in FIG. 3, the width W of the first surface S1 may be a diameter of the first surface S1. In addition, for another example, when the microchip 100 has a square cross-section, the width W of the first surface S1 may be a width or a length of the first surface S1 in one direction. The width W of the first surface S1 may be less than the width K of the second surface S2.

When a distance between the first surface S1 of the chip body 110 and the second surface S2 disposed on the upper surface of the insulating layer 114, that is, a thickness T of the chip body 110, is too large, a force causing the microchip 100 to fall due to an external force may be greater than an adhesion force that attaches the chip body 110 to the circuit board 3. Therefore, the width W of the first surface S1 of the chip body 110 may exceed the distance between the first surface S1 and the second surface S2 (that is, the thickness T of the chip body 110). In other words, an aspect ratio of the microchip 100 may be greater than 0 and less than 1.

According to one or more embodiments, the distance between the first surface S1 and the second surface S2 of the chip body 110, or the thickness T of the chip body 110, may be in the range of about 1 μm or more and about 10 μm or less, or in the range of about 1 μm or more and about 5 μm or less, or in the range of about 2 μm or more and about 3 μm or less.

As described above, as the size of the microchip 100 according to one or more embodiments is reduced and the size of the display device 1 increases, there may be a limit to improving light efficiency by improving a structural defect of the microchip 100. Therefore, in order to improve the light efficiency of the microchip 100, a method of increasing the extraction efficiency of light emitted from the microchip 100 may be considered.

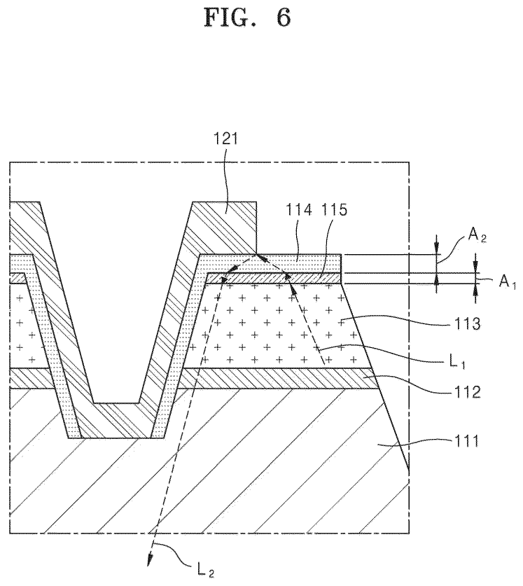

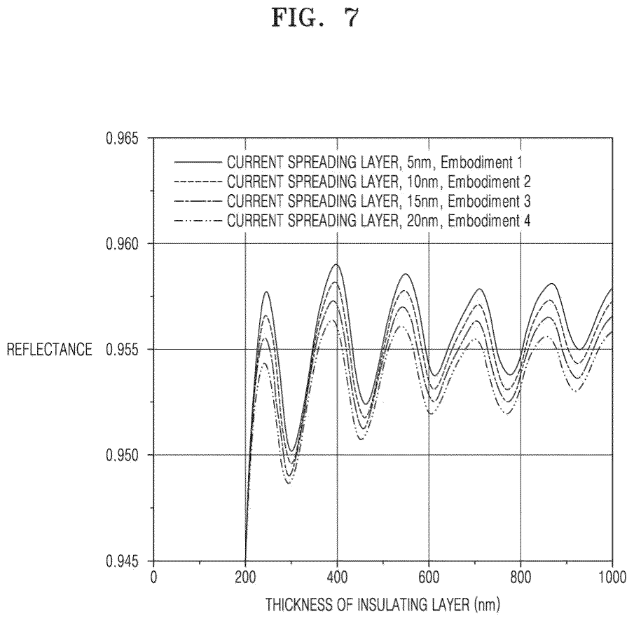

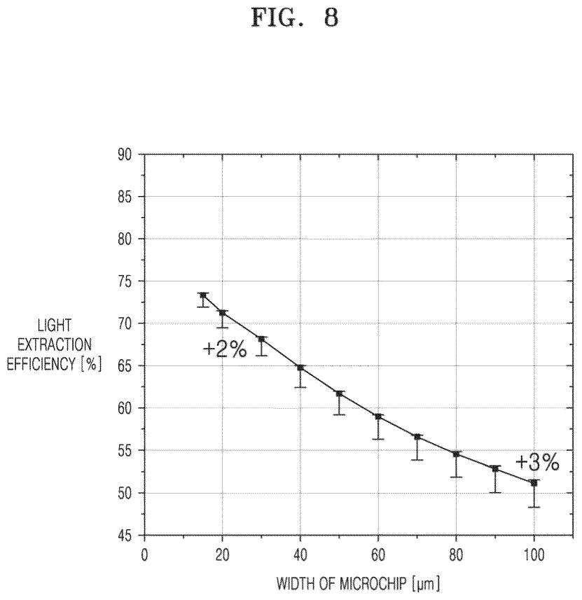

FIG. 6 is an enlarged cross-sectional view illustrating a region M shown in FIG. 5 according to one or more embodiments. FIG. 7 is a graph illustrating reflectance according to a thickness change of the insulating layer 114, according to one or more embodiments. FIG. 8 is a graph illustrating light extraction efficiency according to a length of a width of the microchip 100, according to one or more embodiments.

Referring to FIGS. 4 to 6, light generated from the light emitting layer 112 may be emitted toward the second surface S2. In the light generated from the light emitting layer 112, light L₁ emitted toward the second surface S2 may be reflected by the electrode portion 120 (i.e., a bottom surface of a portion of the first electrode 121 that extends over the insulating layer 114). Reflection light L₂ reflected by the electrode portion 120 may be emitted to the outside toward the first surface S1, thereby improving the extraction efficiency of light emitted from the microchip 100.

When a material having a different refractive index is disposed in an optical path in which the light L₁ generated from the light emitting layer 112 is reflected by the electrode portion 120 and is emitted to the outside toward the first surface S1, an optical path of the reflection light L₂ reflected by the electrode portion 120 may be changed. As described above, the microchip 100 according to one or more embodiments may have a size of submillimeter (mm) or less. For example, the width W of the first surface S1 of the microchip 100 may be in the range of about 5 μm or more and about 100 μm or less. In addition, the thickness T of the chip body 110 may be in the range of about 1 μm or more and about 10 μm or less. When the optical path changes in the microchip 100 having the size of sub-millimeter (mm) or less, the reflection light L₂ may not be emitted to the outside toward the first surface S1. When the reflection light L₂ whose optical path has changed is not emitted to the outside toward the first surface S1, the extraction efficiency of light emitted from the microchip 100 may decrease.

The insulating layer 114 may be disposed between the electrode portion 120 and the first semiconductor layer 111 and between the light emitting layer 112 and the second semiconductor layer 113 to protect the first semiconductor layer 111, the light emitting layer 112, and the second semiconductor layer 113. In addition, the current spreading layer 115 may be disposed between the second semiconductor layer 113 and the insulating layer 114. Accordingly, the insulating layer 114 and the current spreading layer 115 may be disposed between the light emitting layer 112 and the electrode portion 120. The insulating layer 114 may have a thickness A2 that is greater than a thickness A1 of the current spreading layer 115.

As the insulating layer 114 and the current spreading layer 115 according to one or more embodiments are disposed between the light emitting layer 112 and the electrode portion 120, the current spreading layer 115 and the insulating layer 114 may be disposed in the optical path along which the light L₁ emitted toward the second surface S2 moves. The current spreading layer 115 and the insulating layer 114 having different refractive indices may be disposed in the optical path along which the light L₁ emitted toward the second surface S2 moves, and thus, the optical path along which the light L₁ emitted toward the second surface S2 may be changed. When the optical path along which the light L₁ emitted toward the second surface S2 is changed and the reflection light L₂ having the changed optical path is not emitted to the outside toward the first surface S1, the extraction efficiency of light emitted from the microchip 100 may decrease. In order to minimize a decrease in the extraction efficiency of light emitted from the microchip 100, it may be necessary to determine a thickness and a material of each of the insulating layer 114 and the current spreading layer 115, which may affect the optical path.

The insulating layer 114 according to one or more embodiments may include a transparent material such that the reflection light L₂ reflected by the electrode portion 120 may be emitted to the outside toward the first surface S1. For example, the insulating layer 114 may include a material with a refractive index of 1.5 or less. For example, the insulating layer may include one or more of SiO₂ and MgF₂.

The current spreading layer 115 according to one or more embodiments may include a transparent material such that the reflection light L₂ reflected by the electrode portion 120 may be emitted to the outside toward the first surface S1. For example, the current spreading layer 115 may include one or more of indium tin oxide (ITO), ZnO, and indium gallium zinc oxide (IGZO). For example, the current spreading layer 115 may be implemented in the form of a thin film capable of current spreading. For example, the current spreading layer 115 may have a thickness A1 of about 5 nm to about 50 nm, about 5 nm to about 10 nm, about 5 nm to about 15 nm, or about 5 nm to about 20 nm.

According to one or more embodiments, when the current spreading layer 115 is implemented in the form of the thin film and the insulating layer 114 includes the material with the refractive index of 1.5 or less, the extraction efficiency of light emitted from the microchip 100 may be adjusted according to a change in the thickness of the insulating layer 114.

According to one or more embodiments, the light L₁ emitted from the light emitting layer 112 may have a wavelength of about 380 nm or more and about 500 nm or less. The reflection efficiency of the reflection light L₂ reflected by the electrode portion 120 may also change according to a wavelength of the light L₁ emitted from the light emitting layer 112.

The light extraction efficiency may be improved according to the change in the thickness of the insulating layer 114, as is shown in the following Embodiments 1-4.

In Embodiment 1, in the microchip 100, the width W of the first surface S1 of the microchip 100 is 20 μm, and a width of the second surface S2 of the chip body 110, in other words, an upper diameter K, is 16 μm. The thickness T of the chip body 110 is 4 μm. The first semiconductor layer 111 may include nGaN. The light emitting layer 112 includes a plurality of layers of InGaN/GaN. The light emitted from the light emitting layer 112 may have a wavelength of 450 nm. The second semiconductor layer 113 includes pGaN. The insulating layer 114 may include silicon dioxide SiO₂. The current spreading layer 115 includes Indium Tin Oxide (ITO) and has a thickness A1 of 5 nm. The planarization layer 116 includes polydimethylsiloxane (PDMS). The electrode portion 120 performs light reflection and bonding and includes one or more of Al, Sn, Au, Ag, and Pt.

Embodiment 2 is the same as Embodiment 1, except that the thickness A1 of the current spreading layer 115 is 10 nm.

Embodiment 3 is the same as Embodiment 1, except that the thickness A1 of the current spreading layer 115 is 15 nm.

Embodiment 4 is the same as Embodiment 1, except that the thickness A1 of the current spreading layer 115 is 20 nm.

Referring to FIG. 7, in Embodiments 1 to 4, as the thickness of the insulating layer 114 changes, a reflectance of the reflection light L₂ reflected by the electrode portion 120 periodically emitted toward the first surface S1 increases.

For example, when the thickness A1 of the current spreading layer 115 is about 5 nm or more and about 20 nm or less, and the thickness A2 of the insulating layer 114 is about 220 nm or more and about 270 nm or less, the reflectance of the reflection light L₂ reflected by the electrode portion 120 periodically emitted toward the first surface S1 may be improved.

In addition, for example, when the thickness A1 of the current spreading layer 115 is about 5 nm or more and about 20 nm or less, and the thickness A2 of the insulating layer 114 is about 350 nm or more and about 420 nm or less, the reflectance of the reflection light L₂ reflected by the electrode portion 120 periodically emitted toward the first surface S1 may be improved.

In addition, for example, when the thickness A1 of the current spreading layer 115 is about 5 nm or more and about 20 nm or less, and the thickness A2 of the insulating layer 114 is about 520 nm or more and about 580 nm or less, the reflectance of the reflection light L₂ reflected by the electrode portion 120 periodically emitted toward the first surface S1 may be improved.

In addition, for example, when the thickness A1 of the current spreading layer 115 is about 5 nm or more and about 20 nm or less, and the thickness A2 of the insulating layer 114 is about 680 nm or more and about 720 nm or less, the reflectance of the reflection light L₂ reflected by the electrode portion 120 periodically emitted toward the first surface S1 may be improved.

Referring to FIG. 8, the light extraction efficiency of the microchip 100 is improved. In addition, as the width W of the first surface S1 of the microchip 100 increases, the light extraction efficiency of the microchip 100 increases from about 2 % to about 3 %. In other words, as the size of the microchip 100 increases, the effect of optical path interference may be reduced, thereby increasing the light extraction efficiency of the microchip 100.

As described above, with the current spreading layer 115 in the form of the thin film with the thickness A1 of about 5 nm to about 20 nm, and with the insulating layer 114 including the material having the refractive index of 1.5 or less, the reflectance of the reflection light L₂ reflected by the electrode portion 120 is improved. In addition, as the thickness A2 of the insulating layer 114 is set to a certain range, the reflectance of the reflection light L₂ reflected by the electrode portion 120 is improved. As the reflectance of the reflection light L₂ reflected by the electrode portion 120 is improved, the light extraction efficiency of the microchip 100 having the size of submillimeter (mm) or less may be improved.

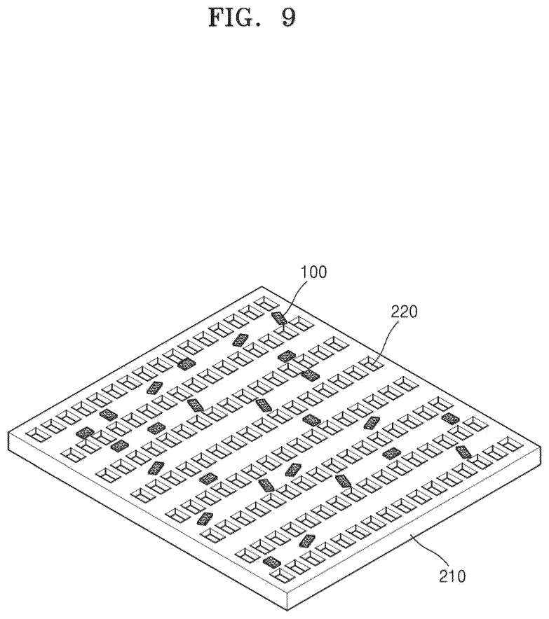

FIG. 9 is a perspective view illustrating a method of aligning a plurality of microchips 100 using a fluid self-assembly method according to one or more embodiments.

Referring to FIG. 9, the plurality of microchips 100 may be supplied on an upper surface of a transfer substrate 210 including a plurality of two-dimensionally arranged grooves 220. After supplying liquid to the grooves 220 of the transfer substrate 210, the plurality of microchips 100 may be directly sprayed on the transfer substrate 210 or supplied on the transfer substrate 210 while included in a suspension.

The liquid supplied to the grooves 220 may be any type of liquid as long as it does not corrode or damage the microchips 100, and may be supplied to the grooves 220 in various ways, such as a spray method, a dispensing method, an inkjet dot method, and a method of flowing the liquid to the transfer substrate 210. The liquid may include, for example, one or a plurality of combinations of groups including water, ethanol, alcohol, polyol, ketone, halocarbon, acetone, flux, and an organic solvent. The organic solvent may include, for example, isopropyl alcohol (IPA). The amount of liquid supplied may be adjusted in various ways to fit the grooves 220 or to overflow from the grooves 220.

The plurality of microchips 100 may be directly sprayed on the transfer substrate 210 without any other liquid, or may be supplied on the transfer substrate 210 while included in the suspension. The microchips 100 included in the suspension may be supplied in various ways such as a spray method, a dispensing method of dropping the liquid in droplets, an inkjet dot method of ejecting the liquid like a printing method, a method of flowing the suspension onto the transfer substrate 210, etc.

In order to align the plurality of microchips 100 on the transfer substrate 210 using the fluid self-assembly method, one surface of the plurality of microchips 100 mounted on the transfer substrate 210 (for example, a lower surface of the first semiconductor layer 111 or a lower surface of the planarization layer 116) may be required to have a planar shape. Accordingly, a plurality of light scattering patterns 117 arranged to improve the light extraction efficiency of the plurality of microchips 100 may be provided by an intaglio process and arranged in a cone-shape or triangle-shape pattern.

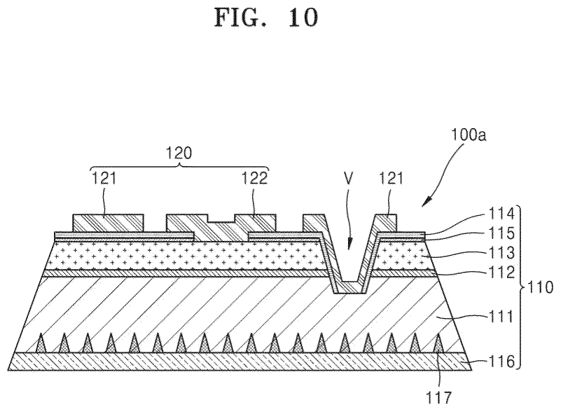

FIG. 10 is a cross-sectional view illustrating a structure of a microchip 100a according to one or more embodiments. Referring to FIG. 10, the microchip 100a may further include the plurality of light scattering patterns 117 disposed in the first semiconductor layer 111. The light scattering patterns 117 may each include air, a void, a transparent dielectric material, or a semiconductor material different from a semiconductor material of the first semiconductor layer 111. The light scattering patterns 117 may each be formed by an intaglio process. The light scattering patterns 117 may have a cone-shape or triangle-shape with a base that is positioned on a lower surface of the first semiconductor layer 111 and on the upper surface of the planarization layer 116. A width, thickness, and shape of the light scattering pattern 117 or distances between the light scattering patterns 117 may be irregularly distributed. Accordingly, light generated from the light emitting layer 112 may be relatively uniformly emitted to the outside by the irregular light scattering patterns 117 in the first semiconductor layer 111.

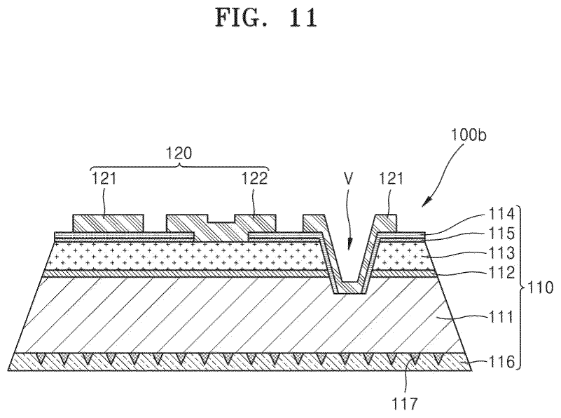

FIG. 11 is a cross-sectional view illustrating a structure of a microchip 100b according to one or more embodiments. Referring to FIG. 11, the microchip 100b may include the plurality of light scattering patterns 117 disposed in the planarization layer 116 instead of the first semiconductor layer 111. For example, the light scattering patterns 117 may each be formed in an intaglio process. The light scattering patterns 117 may have a cone-shape or triangle-shape with a base that is positioned on the upper surface of the planarization layer 116 and the lower surface the first semiconductor layer 111. In FIG. 11, the light scattering patterns 117 may extend downward into the planarization layer 116.

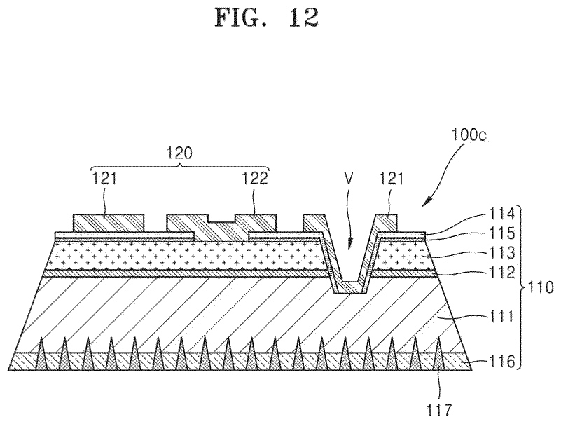

FIG. 12 is a cross-sectional view illustrating a structure of a microchip 100c according to one or more embodiments. Referring to FIG. 12, the microchip 100c may include the plurality of light scattering patterns 117 that penetrate the planarization layer 116, are formed in an intaglio process, and have a cone-shape or triangle-shape with a base that is positioned on a lower surface of the planarization layer 116. The plurality of light scattering patterns 117 may extend upward from the lower surface of the planarization layer 116 into the first semiconductor layer 111. The plurality of light scattering patterns 117 may be two-dimensionally arranged apart from each other. In this case, a surface roughness of a first surface of the chip body 110 of the microchip 100c (that is, a lower surface of the planarization layer 116) may be measured excluding the plurality of light scattering patterns 117. Because the plurality of light scattering patterns 117 are separated from each other, the lower surface of the planarization layer 116 may include portions that are still capable of adhesion. Therefore, even when the light scattering patterns 117 are formed by penetrating the planarization layer 116, the adhesion between the lower surface of the planarization layer 116 and an external contact surface may not be significantly reduced.

In the above-described embodiment, the plurality of light scattering patterns 117 are formed by an intaglio process and are arranged in a pattern of cone shapes or triangle shapes in consideration of an example of using a fluid self-assembly method to align the plurality of microchips 100, but the disclosure is limited thereto.

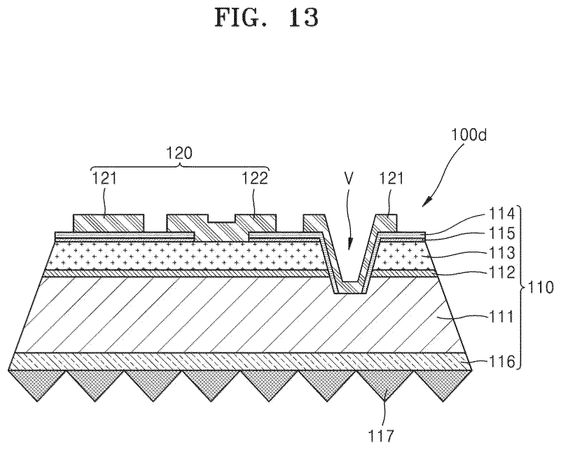

FIG. 13 is a cross-sectional view illustrating a structure of a microchip 100d according to one or more embodiments. Referring to FIG. 13, the microchip 100d may include the plurality of light scattering patterns 117 disposed on a lower surface of the planarization layer 116. For example, the light scattering patterns 117 may be formed by an embossing process, and may have cone shapes or triangle shapes extending from the lower surface of the planarization layer 116.

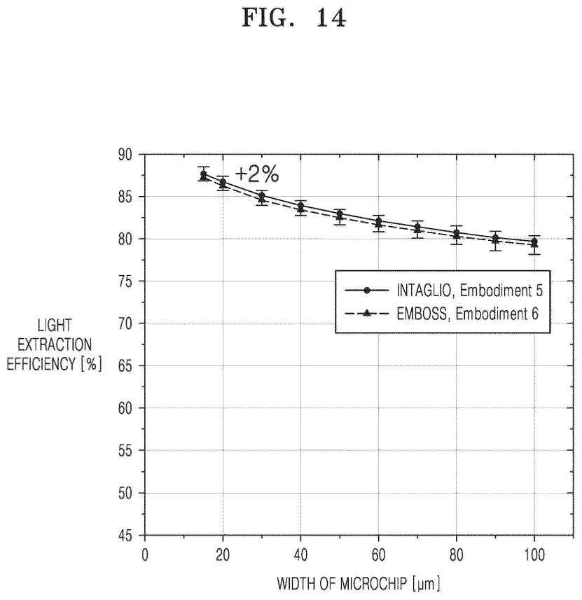

FIG. 14 is a graph illustrating light extraction efficiency according to a length of a width of the microchip 100 according to one or more embodiments.

In the microchip 100 of Embodiment 5, the width W of the first surface S1 of the microchip 100 is 20 μm, and the width W of the second surface S2 of the chip body 110 (the upper diameter K) is 16 μm. The thickness T of the chip body 110 is 4 μm. The first semiconductor layer 111 includes nGaN. The light emitting layer 112 includes a plurality of layers of InGaN/GaN. Light emitted from the light emitting layer 112 may have a wavelength of 450 nm. The second semiconductor layer 113 includes pGaN. The insulating layer 114 may include silicon dioxide (SiO₂). The current spreading layer 115 includes ITO and has a thickness of about 5 nm to about 100 nm. The planarization layer 116 includes polydimethylsiloxane (PDMS). The electrode portion 120 performs light reflection and bonding and includes one or more of Al, Sn, Au, Ag, and Pt. The plurality of light scattering patterns 117 are formed by an intaglio process as shown in FIG. 12. Each of the light scattering patterns 117 has a truncated cone shape with a diameter of 5000 nm or less and a height of 3000 nm or less.

In Embodiment 6, the plurality of light scattering patterns 117 may be formed by the embossing process as shown in FIG. 13. Each of the light scattering patterns 117 has a truncated cone shape with a diameter of 5000 nm or less and a height of 3000 nm or less, and includes a GaN material.

Referring to FIG. 14, the light extraction efficiency of the microchip 100 increases in Embodiments 5 to 6 in which the plurality of light scattering patterns 117 are arranged compared to Embodiment 1 disclosed in FIG. 8.

In addition, the light extraction efficiency of the microchip 100 disclosed in Embodiments 5 to 6 is improved by approximately 2%.

As described above, as the current spreading layer 115 in the form of a thin film with a thickness A1 of about 5 nm to about 50 nm is disposed, and the insulating layer 114 including a material having a refractive index of 1.5 or less is disposed, the reflection efficiency of the reflection light L₂ reflected by the electrode portion 120 is improved. In addition, as a thickness A2 of the insulating layer 114 is set to a certain range, the reflection efficiency of the reflection light L₂ reflected by the electrode portion 120 is improved. As the reflection efficiency of the reflection light L₂ reflected by the electrode portion 120 is improved, the light extraction efficiency of the microchip 100 having a size of submillimeter (mm) or less may be improved.

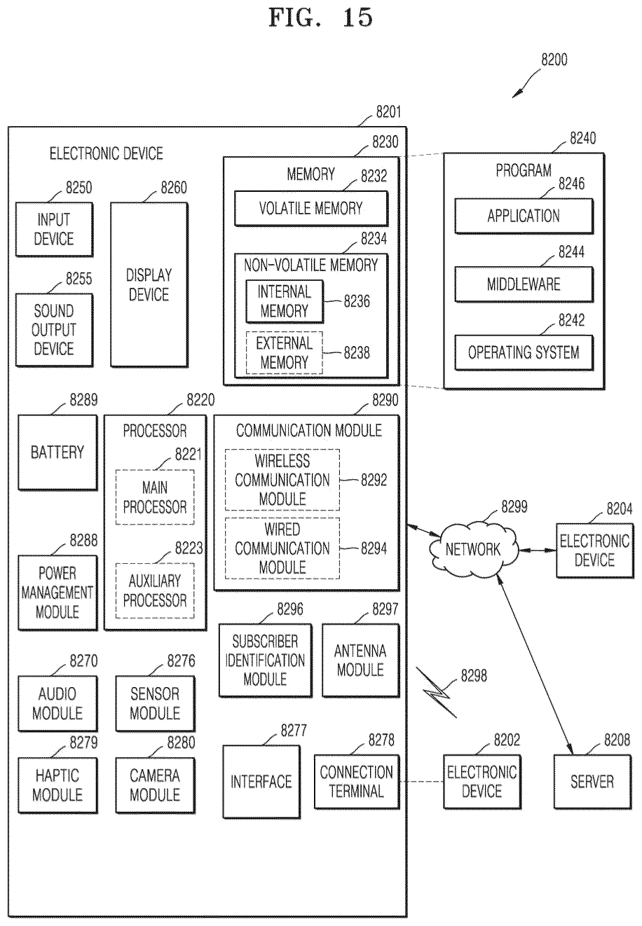

The above-described display devices may be applied to various electronic devices each having a screen display function. FIG. 15 is a schematic block diagram of an electronic device according to one or more embodiments. Referring to FIG. 15, an electronic device 8201 may be provided in a network environment 8200. In the network environment 8200, the electronic device 8201 may communicate with another electronic device 8202 through a first network 8298 (a short-range wireless communication network, etc.) or communicate with another electronic device 8204 and/or a server 8208 through a second network 8299 (a long-distance wireless communication network, etc.). The electronic device 8201 may communicate with the electronic device 8204 through the server 8208. The electronic device 8201 may include a processor 8220, a memory 8230, an input device 8250, an sound output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic device 8201, some of components may be omitted or other components may be added. Some of the components may be implemented by one integrated circuit. For example, the sensor module 8276 (a fingerprint sensor, an iris sensor, an illuminance sensor, etc.) may be implemented by being embedded in the display device 8260 (a display, etc.).

The processor 8220 may control one or a plurality of other components (hardware and software components, etc.) of the electronic device 8201 connected to the processor 8220 by executing software (a program 8240, etc.), and perform various data processing or calculations. As part of the data processing or calculations, the processor 8220 may load, in a volatile memory 8232, commands and/or data received from other components (the sensor module 8276, the communication module 8290, etc.), process the command and/or data stored in the volatile memory 8232, and store result data in a non-volatile memory 8234. The non-volatile memory 8234 may include an internal memory 8236 and an external memory 8238 mounted in the electronic device 8201. The processor 8220 may include a main processor 8221 (a central processing unit, an application processor, etc.) and an auxiliary processor 8223 (a graphics processing unit, an image signal processor, a sensor hub processor, a communication processor, etc.) that is operable independently of or together with the main processor 8221. The auxiliary processor 8223 may use less power than the main processor 8221 and may perform a specialized function.

Instead of the main processor 8221 when the main processor 8221 is in an inactive state (sleep state), or with the main processor 8221 when the main processor 8221 is in an active state (application execution state), the auxiliary processor 8223 may control functions and/or states related to some components (the display device 8260, the sensor module 8276, the communication module 8290, etc.) of the components of the electronic device 8201. The auxiliary processor 8223 (an image signal processor, a communication processor, etc.) may be implemented as a part of functionally related other components (the camera module 8280, the communication module 8290, etc.).

The memory 8230 may store various data needed by the components (the processor 8220, the sensor module 8276, etc.) of the electronic device 8201. The data may include, for example, software (the program 8240, etc.) and input data and/or output data of commands related thereto. The memory 8230 may include the volatile memory 8232 and/or the non-volatile memory 8234.

The program 8240 may be stored in the memory 8230 as software, and may include an operating system 8242, middleware 8244, and/or an application 8246.

The input device 8250 may receive commands and/or data to be used for components (the processor 8220, etc.) of the electronic device 8201, from the outside (a user, etc.) of the electronic device 8201. The input device 8250 may include a remote controller, a microphone, a mouse, a keyboard, and/or a digital pen (a stylus pen, etc.).

The sound output device 8255 may output an audio signal to the outside of the electronic device 8201. The sound output device 8255 may include a speaker and/or a receiver. The speaker may be used for general purposes such as multimedia playback or recording playback, and the receiver may be used to receive incoming calls. The receiver may be implemented by being coupled as a part of the speaker or by an independent separate device.

The display device 8260 may visually provide information to the outside of the electronic device 8201. The display device 8260 may include a display, a hologram device, or a projector, and a control circuit to control a corresponding device. The display device 8260 may include the display device according to one or more embodiments. The display device 8260 may include a touch circuitry set to detect a touch and/or a sensor circuit (a pressure sensor, etc.) set to measure the strength of a force generated by the touch.

The audio module 8270 may convert sound into electrical signals or reversely electrical signals into sound. The audio module 8270 may obtain sound through the input device 8250, or output sound through a speaker and/or a headphone of another electronic device (the electronic device 8202, etc.) directly or wirelessly connected to the sound output device 8255 and/or the electronic device 8201.

The sensor module 8276 may detect an operation state (power, temperature, etc.) of the electronic device 8201, or an external environment state (a user state, etc.), and generate an electrical signal and/or a data value corresponding to a detected state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more specified protocols used for the electronic device 8201 to be directly or wirelessly connected to another electronic device (the electronic device 8202, etc.) The interface 8277 may include a high-definition multimedia interface (HDMI), a universal serial bus (USB) interface, a secure digital (SD) card interface, and/or an audio interface.

A connection terminal 8278 may include a connector for the electronic device 8201 to be physically connected to another electronic device (the electronic device 8202, etc.) The connection terminal 8278 may include an HDMI connector, a USB connector, an SD card connector, and/or an audio connector (a headphone connector, etc.).

The haptic module 8279 may convert electrical signals into mechanical stimuli (vibrations, movements, etc.) or electrical stimuli that are perceivable by a user through tactile or motor sensations. The haptic module 8279 may include a motor, a piezoelectric device, and/or an electrical stimulation device.

The camera module 8280 may capture a still image and a video. The camera module 8280 may include a lens assembly including one or more lenses, image sensors, image signal processors, and/or flashes. The lens assembly included in the camera module 8280 may collect light emitted from a subject that is a target of image capturing.

The power management module 8288 may manage power supplied to the electronic device 8201. The power management module 1188 may be implemented as a part of a power management integrated circuit (PMIC).

The battery 8289 may supply power to the components of the electronic device 8201. The battery 8289 may include non-rechargeable primary cells, rechargeable secondary cells, and/or fuel cells.

The communication module 8290 may establish a wired communication channel and/or a wireless communication channel between the electronic device 8201 and another electronic device (the electronic device 8202, the electronic device 8204, the server 8208, and the like), and support a communication through an established communication channel. The communication module 8290 may be operated independent of the processor 8220 (the application processor, etc.), and may include one or more communication processors supporting a direct communication and/or a wireless communication. The communication module 8290 may include a wireless communication module 8292 (a cellular communication module, a short-range wireless communication module, a global navigation satellite system (GNSS) communication module, etc.), and/or a wired communication module 8294 (a local area network (LAN) communication module, a power line communication module, etc.). Among the above communication modules, a corresponding communication module may communicate with another electronic device through the first network 8298 (a short-range communication network such as Bluetooth, WiFi Direct, or infrared data association (IrDA)) or the second network 8299 (a long-range communication network such as a cellular network, the Internet, or a computer network (LAN, WAN, etc.)). These various types of communication modules may be integrated into one component (a single chip, etc.), or may be implemented as a plurality of separate components (multiple chips). The wireless communication module 8292 may verify and authenticate the electronic device 8201 in a communication network such as the first network 8298 and/or the second network 8299 using subscriber information (an international mobile subscriber identifier (IMSI), and the like) stored in the subscriber identification module 8296.

The antenna module 8297 may transmit signals and/or power to the outside (another electronic device, etc.) or receive signals and/or power from the outside. An antenna may include an emitter formed in a conductive pattern on a substrate (a printed circuit board (PCB), etc.). The antenna module 8297 may include one or a plurality of antennas. When the antenna module 8297 includes a plurality of antennas, the communication module 8290 may select, from among the antennas, an appropriate antenna for a communication method used in a communication network such as the first network 8298 and/or the second network 8299. Signals and/or power may be transmitted or received between the communication module 8290 and another electronic device through the selected antenna. Other parts (an RFIC, and the like) than the antenna may be included as a part of the antenna module 8297.

Some of the components may be connected to each other through a communication method between peripheral devices (a bus, general purpose input and output (GPIO), a serial peripheral interface (SPI), a mobile industry processor interface (MIPI), etc.) and may mutually exchange signals (command, data, etc.).

The command or data may be transmitted or received between the electronic device 8201 and the external electronic device 8204 through the server 8208 connected to the second network 8299. The electronic devices 8202 and 8204 may be of a type that is the same as or different from the electronic device 8201. All or some of operations executed in the electronic device 8201 may be executed in one or more of the other electronic devices 8202, 8204, and 8208. For example, when the electronic device 8201 needs to perform a function or service, the electronic device 8201 may request one or more electronic devices to perform part or the whole of the function or service, instead of performing the function or service. The one or more electronic devices receiving the request may perform additional function or service related to the request, and transmit a result of the performance to the electronic device 8201. To this end, cloud computing, distributed computing, and/or client-server computing technology may be used.

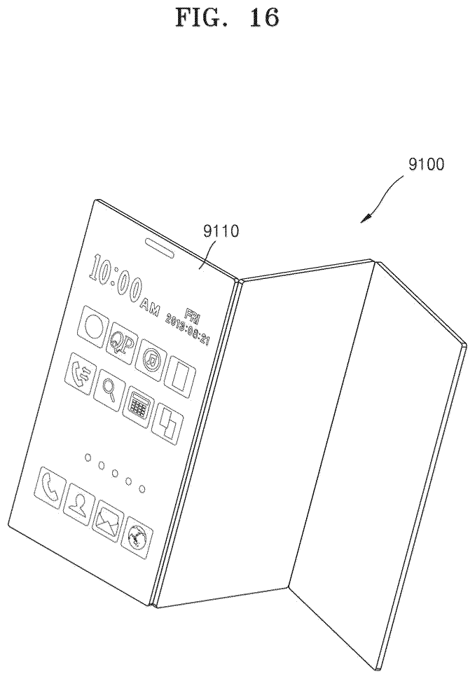

FIG. 16 is a diagram illustrating an example in which a display device is applied to a mobile device according to one or more embodiments. A mobile device 9100 may include a display device 9110, and the display device 9110 may include the circuit board, the microchip, etc. described above. The display device 9110 may have a foldable structure, for example, a multi-foldable structure.

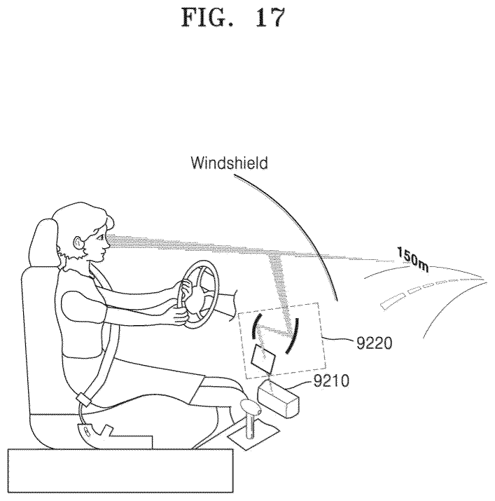

FIG. 17 is a diagram illustrating an example in which a display device is applied to a display device for vehicles according to one or more embodiments. The display device may be a head-up display device for vehicles 9200 and may include a display 9210 and an optical path change member 9220 configured to change an optical path so that a driver may see an image generated on the display 9210.

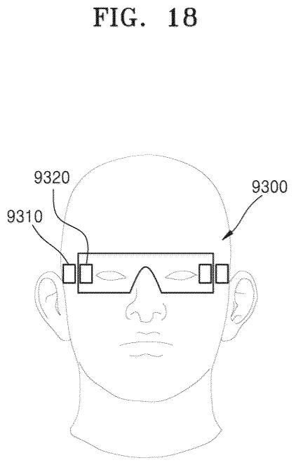

FIG. 18 is a diagram illustrating an example in which a display device is applied to augmented reality glasses or virtual reality glasses according to one or more embodiments. Augmented reality glasses 9300 may include a projection system 9310 configured to form an image and an element 9320 configured to guide the image from the projection system 9310 to user's eyes. The projection system 9310 may include the circuit board, the microchip, etc. described above.

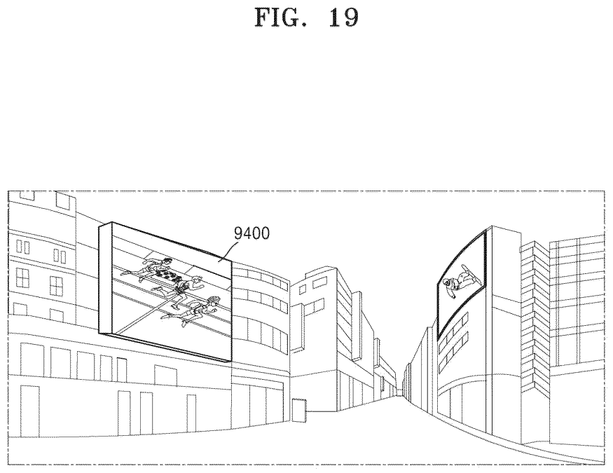

FIG. 19 is a diagram illustrating an example in which a display device is applied to signage according to one or more embodiments. A signage 9400 may be used in outdoor advertising using a digital information display, and may control contents, etc. of an advertisement though a network. The signage 9400 may be implemented by, for example, the electronic device described with reference to FIG. 15.

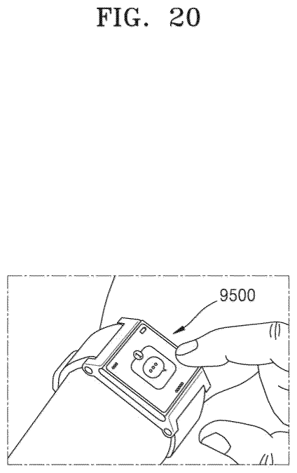

FIG. 20 is a diagram illustrating an example in which a display device is applied to a wearable display according to one or more embodiments. A wearable display 9500 may include the circuit board, the microchip, etc. described above, and may be implemented by the electronic device described with reference to FIG. 15.

The display device according to one or more embodiments may also be applied to various products such as rollable television (TV), stretchable display, etc.

The microchip including the insulating layer and the current spreading layer according to one or more embodiments may have improved light extraction efficiency.

In addition, the display device according to one or more embodiments may be manufactured in a large area using a fluid self-assembly method using the microchip with a structure suitable for alignment using the fluid self-assembly method.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A microchip comprising:
a first semiconductor layer having a first conductivity type and extending along one plane;
a light emitting layer on an upper surface of the first semiconductor layer;
a second semiconductor layer on an upper surface of the light emitting layer and having a second conductivity type that is electrically opposite to the first conductivity type;
an insulating layer on an upper surface of the second semiconductor layer; and
a current spreading layer between the second semiconductor layer and the insulating layer,
wherein the insulating layer comprises a material having a refractive index that is less than or equal to 1.5, and
wherein the current spreading layer has a thickness that is in a range of about 5 nm to about 50 nm.

2. The microchip of claim 1, wherein the insulating layer has a thickness that is in a range of about 220 nm to about 270 nm.

3. The microchip of claim 1, wherein the insulating layer has a thickness that is in a range of about 350 nm to about 420 nm.

4. The microchip of claim 1, wherein the insulating layer has a thickness that is in a range of about 520 nm to about 580 nm.

5. The microchip of claim 1, wherein the insulating layer has a thickness that is in a range of about 680 nm to about 720 nm.

6. The microchip of claim 1, wherein the light emitting layer is configured to emit light in a wavelength that is in a range of about 380 nm to and about 500 nm.

7. The microchip of claim 1, wherein the insulating layer comprises at least one of SiO₂ and MgF₂.

8. The microchip of claim 1, wherein the current spreading layer comprises at least one of indium tin oxide (ITO), ZnO, and indium gallium zinc oxide (IGZO).

9. The microchip of claim 1, further comprising:
a first electrode on an upper surface of the insulating layer and connected to the first semiconductor layer; and
a second electrode on the upper surface of the insulating layer and connected to the second semiconductor layer.

10. The microchip of claim 9, wherein the microchip comprises a first surface having a width that is greater than a width of the upper surface of the insulating layer.

11. The microchip of claim 9, wherein the microchip comprises a first surface having a width that is in a range of about 5 μm to about 100 μm.

12. The microchip of claim 10, wherein the microchip comprises a first surface, and
wherein a distance between the first surface and the upper surface of the insulating layer is in a range of about 1 μm to about 10 μm.

13. The microchip of claim 1, further comprising a planarization layer on a lower surface of the first semiconductor layer.

14. The microchip of claim 13, wherein the planarization layer comprises at least one of aluminum nitride, polyimide, and parylene.

15. The microchip of claim 13, further comprising a plurality of light scattering patterns in the first semiconductor layer,
wherein each of the plurality of light scattering patterns has an intaglio shape with a base on the lower surface of the first semiconductor layer that contacts an upper surface of the planarization layer.

16. The microchip of claim 13, further comprising a plurality of light scattering patterns in the planarization layer,
wherein the plurality of light scattering patterns have an intaglio shape with a base on an upper surface of the planarization layer.

17. The microchip of claim 13, further comprising a plurality of light scattering patterns penetrating the planarization layer and having an intaglio shape with a base on the lower surface of the first semiconductor layer.

18. A display device comprising:
a circuit board comprising a driving circuit; and
a plurality of microchips on the circuit board,
wherein each of the plurality of microchips comprises:
a first semiconductor layer having a first conductivity type and extending along one plane;
a light emitting layer on an upper surface of the first semiconductor layer;
a second semiconductor layer on an upper surface of the light emitting layer and having a second conductivity type that is electrically opposite to the first conductivity type;
an insulating layer on an upper portion of the second semiconductor layer; and
a current spreading layer between the second semiconductor layer and the insulating layer,
wherein the insulating layer comprises a material having a refractive index of 1.5 or less, and
wherein the current spreading layer has a thickness that is in a range of about 5 nm to about 50 nm.

19. The display device of claim 18, wherein the insulating layer has a thickness that is in a range of about 220 nm to about 270 nm.

20. The display device of claim 18, wherein the insulating layer has a thickness that is in a range of about 350 nm to about 420 nm.

21. The display device of claim 18, wherein the insulating layer has a thickness that is in a range of about 520 nm to about 580 nm.

22. The display device of claim 18, wherein the insulating layer has a thickness that is in a range of about 680 nm to about 720 nm.

23. The display device of claim 18, wherein the light emitting layer is configured to emit light in a wavelength that is in a range of about 380 nm to about 500 nm.

24. The display device of claim 18, further comprising:
a plurality of first electrode pads on a first surface of the circuit board; and
a plurality of second electrode pads on the first surface of the circuit board,
wherein each of the plurality of microchips further comprises:
a first electrode on an upper surface of the insulating layer and connected to the first semiconductor layer; and
a second electrode on the upper surface of the insulating layer and connected to the second semiconductor layer,
wherein the first electrode of each of the plurality of microchips contacts one of the plurality of first electrode pads, and
wherein the second electrode of each of the plurality of microchips contacts one of the plurality of second electrode pads.
